(19) United States
(12) Patent Application Publication
(10) Pub. No.: US 2026/0072536 A1
(43) Pub. Date: Mar. 12, 2026

(54) TOUCH PANEL DISPLAY DEVICE

(71) Applicant: FUJIFILM Corporation, Tokyo (JP)

(72) Inventor: Masaya NAKAYAMA, Kanagawa (JP)

(73) Assignee: FUJIFILM Corporation, Tokyo (JP)

(21) Appl. No.: 19/313,777

(22) Filed: Aug. 28, 2025

(30) Foreign Application Priority Data
Sep. 12, 2024 (JP) 2024-157894

(51) Int. Cl. G06F 3/041; H10K 59/40

(52) U.S. Cl. CPC G06F 3/0414; G06F 3/0412; H10K 59/40

(57) ABSTRACT

An object of the present invention is to provide a touch panel display device that has excellent contrast between black display and white display in a case of black-and-white display and has excellent performance of suppressing a decrease in contrast in a high-temperature and high-humidity environment.

A touch panel display device according to an aspect of the present invention is a touch panel display device including a cover member, a first pressure-sensitive adhesive layer, a touch sensor, a second pressure-sensitive adhesive layer, and an organic electroluminescence display panel in this order, in which the touch sensor has an acrylic substrate, a thickness of the acrylic substrate is 40 μm or less, and a thickness of the second pressure-sensitive adhesive layer is 100 μm or less.

### CROSS-REFERENCE TO RELATED APPLICATIONS

The present application claims priority under 35 U.S.C. § 119 to Japanese Patent Application No. 2024-157894 filed on Sep. 12, 2024. The above application is hereby expressly incorporated by reference, in its entirety, into the present application.

### BACKGROUND OF THE INVENTION

### 1. Field of the Invention

The present invention relates to a touch panel display device.

### 2. Description of the Related Art

In the related art, in various electronic apparatuses including portable information apparatuses such as a tablet-type computer and a smartphone, a touch sensor that detects a so-called touch operation of allowing a finger or a stylus pen to contact or approach a screen has been used. Such a touch sensor is usually formed on a surface of a substrate and has a detection electrode that detects a touch operation.

For example, JP2018-116746A discloses a flexible electrode member for a touch panel, which includes a transparent flexible substrate, a sensor electrode formed on at least one surface of the transparent flexible substrate, and a lead-out circuit for electrically connecting the sensor electrode to an external circuit, a touch panel including the flexible electrode member for a touch panel, and an image display device obtained by disposing the touch panel on a display surface of an image display panel.

### SUMMARY OF THE INVENTION

In a touch panel display device having an image display element and a touch sensor, an example in which an image display element capable of achieving high contrast is used has been increasing in recent years. In addition, a touch panel display device in which a deterioration in performance under severe conditions such as a high temperature and a high humidity environment is suppressed is required as the touch panel display device.

While referring to the technique disclosed in JP2018-116746A, the present inventors have studied the display performance of a touch panel display device in which a touch sensor and an organic electroluminescence (EL) display panel are combined, and have found that there is room for improvement in contrast between black display and white display in a case of black-and-white display in which white and black are displayed at the same time, and in resistance of the touch panel display device to a high temperature and a high humidity environment.

In view of the above circumstances, an object of the present invention is to provide a touch panel display device that has excellent contrast between black display and white display in a case of black-and-white display and has excellent performance of suppressing a decrease in contrast in a high-temperature and high-humidity environment.

The present inventors have conducted extensive studies to accomplish the object, and as a result, have completed the present invention. That is, the present inventors have found that the above-described objects can be achieved by the following configuration.
[1]

A touch panel display device comprising, in the following order: a cover member; a first pressure-sensitive adhesive layer; a touch sensor; a second pressure-sensitive adhesive layer; and an organic electroluminescence display panel, in which the touch sensor has an acrylic substrate, a thickness of the acrylic substrate is 40 μm or less, and a thickness of the second pressure-sensitive adhesive layer is 100 μm or less.
[2]

The touch panel display device according to [1], in which the acrylic substrate includes polymethyl methacrylate.
[3]

The touch panel display device according to [1] or [2], in which the thickness of the acrylic substrate is 35 μm or less.
[4]

The touch panel display device according to any one of [1] to [3], in which the thickness of the second pressure-sensitive adhesive layer is 50 μm or less.
[5]

The touch panel display device according to any one of [1] to [4], in which a total of the thickness of the acrylic substrate and the thickness of the second pressure-sensitive adhesive layer is 56 μm or more.
[6]

The touch panel display device according to any one of [1] to [5], in which the thickness of the second pressure-sensitive adhesive layer is 50 μm or less, and a total of the thickness of the acrylic substrate and the thickness of the second pressure-sensitive adhesive layer is 56 μm or more.
[7]

The touch panel display device according to any one of [1] to [6], in which a thickness of the first pressure-sensitive adhesive layer is 100 μm or less.
[8]

The touch panel display device according to any one of [1] to [7], in which a relative permittivity of the second pressure-sensitive adhesive layer at a frequency of 100 kHz is 3.5 or less.
[9]

The touch panel display device according to any one of [1] to [8], in which both the first pressure-sensitive adhesive layer and the second pressure-sensitive adhesive layer contain an acrylic resin.
[10]

The touch panel display device according to any one of [1] to [9], in which the touch sensor has a detection electrode disposed on at least one surface of the acrylic substrate, and the detection electrode has a mesh pattern formed of fine metal wires.
[11]

The touch panel display device according to [10], in which a line width of the fine metal wires is 2.5 μm or less.

According to the present invention, it is possible to provide a touch panel display device that has excellent contrast between black display and white display in a case of black-and-white display and has excellent performance of suppressing a decrease in contrast in a high-temperature and high-humidity environment.

### BRIEF DESCRIPTION OF THE DRAWINGS

FIG. 1 is a cross-sectional view schematically showing an example of a touch panel display device according to the embodiment of the present invention.

FIG. 2 is a plan view showing an example of a detection electrode of the touch sensor.

### DESCRIPTION OF THE PREFERRED EMBODIMENTS

Hereinafter, a touch panel display device according to the embodiment of the present invention will be described in detail with reference to the drawings.

The following configuration requirements will be described based on the representative embodiment of the present invention; however, the present invention is not limited only to such an embodiment. In addition, each drawing is shown for describing the present invention, and the scale of each component may be changed from the actual scale for easy visibility or description.

In the present specification, numerical ranges represented by “to” include numerical values before and after “to” as lower limit values and upper limit values.

In the present specification, in a case where there are two or more components corresponding to a certain component, “content” of such a component means the total content of the two or more components.

The term “orthogonal” or “perpendicular” with respect to an angle means a range of 90°±5°, and the term “parallel” means a range of 0°±5°. Similarly, unless otherwise specified, an angle represented by a specific numerical value means that a difference from an exact angle is within 5 degrees. The difference between the above-described orthogonality, verticality, and parallelism and the above-described angle and the exact angle is preferably within 4 degrees and more preferably within 3 degrees.

The terms “polymer”, “high polymer”, or “polymer compound” each mean a compound having a weight-average molecular weight of 2,000 or more. Here, the weight-average molecular weight is defined as a polystyrene equivalent value measured by gel permeation chromatography (GPC) under the following conditions.
Device: HLC-8320GPC manufactured by Tosoh Corporation
Column: TSK-GEL G3000PWXL manufactured by Tosoh Corporation
Column Temperature: 35° C.
Flow Rate: 0.5 mL/min
Calibration Curve: POLY SODIUM ACRYLATE STANDARD manufactured by Sowa Kagaku K.K.
Eluent: a solution prepared by diluting a mixture of sodium dihydrogen phosphate dodecahydrate/disodium hydrogen phosphate dihydrate (34.5 g/46.2 g) to 5,000 g with pure water

A “main surface” means a surface having the largest area in a film-like, sheet-like, or plate-like member.

The term “visible light” means light in a wavelength range of 380 to 780 nm.

The term “transparent” means that a light transmittance in a visible wavelength range is 40% or more, preferably 60% or more, more preferably 80% or more, and still more preferably 90% or more. The light transmittance is measured according to “Plastics-Determination of Total Luminous Transmittance and Reflectance” specified in JIS K 7375:2008 by using known transmittance measurement equipment.

In the present specification, the term “acrylic resin” is used to mean one or both of a polymer and a copolymer in which a content of a unit derived from at least one monomer (a (meth)acrylate monomer) selected from the group consisting of acrylate and methacrylate is 50% by mole or more with respect to all the units.

### Touch Panel Display Device

A touch panel display device according to the embodiment of the present invention includes a cover member, a first pressure-sensitive adhesive layer, a touch sensor, a second pressure-sensitive adhesive layer, and an organic electroluminescence (EL) display panel (hereinafter, also referred to as an “OLED panel”) in this order.

Hereinafter, the display device will be described in detail with reference to the drawings.

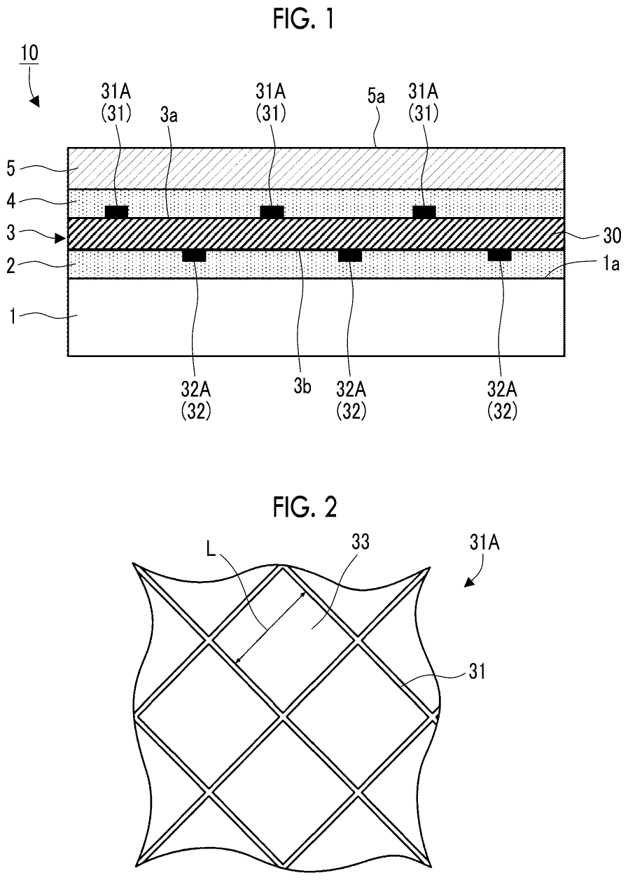

FIG. 1 is a schematic cross-sectional view showing an example of a touch panel display device according to the embodiment of the present invention.

In the touch panel display device 10 shown in FIG. 1, an OLED panel 1, a second pressure-sensitive adhesive layer 2, a touch sensor 3, a first pressure-sensitive adhesive layer 4, and a cover member 5 are disposed in this order in a thickness direction.

The touch sensor 3 has an acrylic substrate 30, a first detection electrode 31A consisting of a fine metal wire 31 disposed on one surface of the acrylic substrate 30, and a second detection electrode 32A consisting of a fine metal wire 32 disposed on the other surface of the acrylic substrate 30. As shown in the drawing, the first pressure-sensitive adhesive layer 4 is disposed to cover the first detection electrode 31A consisting of the fine metal wire 31 on the surface 3a of the touch sensor 3, and the second pressure-sensitive adhesive layer 2 is disposed to cover the second detection electrode 32A consisting of the fine metal wire 32 on the surface 3b of the touch sensor 3.

In the touch panel display device 10, an image displayed on the display surface 1a of the OLED panel 1 is visually recognized through the second pressure-sensitive adhesive layer 2, the touch sensor 3, the first pressure-sensitive adhesive layer 4, and the cover member 5. In addition, a surface 5a of the cover member 5 opposite to the first pressure-sensitive adhesive layer 4 is a touch surface of the touch panel display device 10 and serves as an operation surface.

A touch panel display device according to an embodiment of the present invention comprises a cover member, a first pressure-sensitive adhesive layer, a touch sensor, a second pressure-sensitive adhesive layer, and an organic electroluminescence display panel in this order, in which the touch sensor has an acrylic substrate, a thickness of the acrylic substrate is 40 μm or less, and a thickness of the second pressure-sensitive adhesive layer is 100 μm or less.

The mechanism by which the touch panel display device according to the embodiment of the present invention has an excellent contrast between black display and white display in a case of black-and-white display and has an excellent contrast deterioration suppressing performance in a high-temperature and high-humidity environment is not always clear, but the present inventors suppose as follows.

The present inventors have conducted intensive studies on the problem of the decrease in contrast in a touch panel display device comprising an OLED panel and a touch sensor, and have found that, first, an increase in brightness of black display and a decrease in contrast are not caused by the reflection of external light since the increase in brightness of black display is observed even in a dark room where external light is not present as compared with the black display using only the OLED panel. Further studies were conducted, and it was presumed that the above-described cause may be due to the fact that a part of the light emitted from the white display portion is transmitted or propagated to the black display portion adjacent to the white display portion due to scattering, reflection, or the like in the inside of the substrate of the touch sensor of the touch panel display device and the inside of the pressure-sensitive adhesive layer disposed between the touch sensor and the OLED panel, and as a result, the brightness of black display may increase at a position where an observer observes the display.

On the other hand, in the touch panel display device according to the embodiment of the present invention, it was found by the present inventors that, by using a touch sensor having an acrylic substrate and further setting the thicknesses of the acrylic substrate and the second pressure-sensitive adhesive layer to be within a predetermined range, the contrast between black display and white display in a case of black-and-white display can be significantly improved. From the above-described estimation mechanism, for example, it is presumed that, since the thicknesses of the acrylic substrate and the pressure-sensitive adhesive layer are thin and the refractive indices are close to each other, reflection at the interface between the acrylic substrate and the pressure-sensitive adhesive layer is suppressed, light propagating inside the pressure-sensitive adhesive layer is reduced, and an increase in brightness of the black display adjacent to the white display can be significantly suppressed, and as a result, the contrast between the black display and the white display can be improved.

Further, the present inventors have found that, depending on the type of the substrate of the touch sensor, the contrast between black display and white display in a case of black-and-white display may be reduced in a high temperature and high humidity environment. In the touch panel display device according to the embodiment of the present invention, by using the touch sensor having an acrylic substrate, a decrease in the contrast in a high-temperature and high-humidity environment can be suppressed.

Each member included in the touch panel display device according to the embodiment of the present invention will be described in more detail.

Hereinafter, the touch panel display device according to the embodiment of the present invention will also be referred to as “the present display device”.

In addition, in the present specification, the description that “the effect of the present invention is excellent” means that at least one of a contrast between black display and white display in a case of black-and-white display in the touch panel display device (hereinafter, also simply referred to as “contrast”) or a performance of suppressing a decrease in contrast before and after storage of the touch panel display device in a high temperature and high humidity environment (hereinafter, also referred to as “moisture-heat resistance”) is excellent.

### Touch Sensor

The touch sensor is a film that functions as a sensor that detects a touch operation, and has an acrylic substrate having a thickness of 40 μm or less.

Specific examples of the touch sensor include a touch sensor 3 having an acrylic substrate 1, a detection electrode 11 disposed on one surface of the acrylic substrate 1, and a detection electrode 12 disposed on the other surface of the acrylic substrate 1, as shown in FIG. 1.

The touch sensor is not limited to the aspect shown in FIG. 1. For example, the detection electrode may be disposed only on one surface of the acrylic substrate.

### Acrylic Substrate

The acrylic substrate is a member having a function of supporting the detection electrode. In addition, the acrylic substrate means a substrate containing an acrylic resin as a main component. The definition of the acrylic resin is as described above.

In addition, the expression “contains an acrylic resin as a main component” means that the content of the acrylic resin is greater than 50% by mass with respect to the total mass of the substrate. The content of the acrylic resin is preferably 80% by mass or more, and more preferably 90% by mass or more with respect to the total mass of the acrylic substrate. The upper limit is not particularly limited and may be 100% by mass.

Examples of the acrylic resin constituting the acrylic substrate include polymethyl methacrylate (PMMA), polyacrylonitrile (PAN), sodium polyacrylate (PANa), polyacrylamide (PAAm), and polyacrylic acid ester (PAA). From the viewpoint of moisture-heat resistance of the touch panel display device and touch panel sensitivity, it is more preferable that the acrylic substrate contains PMMA.

The acrylic substrate may further include additives such as a light stabilizer, an antioxidant, an ultraviolet absorber, a flame retardant, an easy slip agent (fine particles), a nucleating agent (crystallization agent), and a crystallization inhibitor, in addition to the acrylic resin.

In addition, the acrylic substrate may further include a visible light absorbing material.

An undercoat layer may be provided on at least one of both main surfaces of the acrylic substrate.

In a case where the undercoat layer is provided, the undercoat layer is preferably installed between the detection electrode and the acrylic substrate. The undercoat layer may be disposed on both main surfaces of the acrylic substrate.

Examples of the material constituting the undercoat layer include a binder resin and a surfactant. As the binder resin, for example, the above-described acrylic resin can be used.

The thickness of the acrylic substrate is 40 μm or less, and from the viewpoint that the effect of the present invention is more excellent, the thickness is preferably 35 μm or less and more preferably 31 μm or less. In addition, from the viewpoint that the strength of the touch sensor and the touch panel display device is more excellent, the thickness of the acrylic substrate is more preferably 10 μm or more.

In a case where the undercoat layer is provided on the acrylic substrate, the thickness of the acrylic substrate does not include the thickness of the undercoat layer.

The thicknesses of the acrylic substrate, the first pressure-sensitive adhesive layer, and the second pressure-sensitive adhesive layer can be measured, for example, by observing a cross section in a thickness direction using a scanning electron microscope (SEM) and measuring the thickness from the obtained observation image.

### Detection Electrode

The detection electrode is a member that functions as a sensor electrode for detecting a touch operation.

The detection electrode is composed of, for example, a plurality of fine metal wires.

It is preferable that the touch sensor has a plurality of first detection electrodes 31A extending in a first direction in a plane on one surface of the acrylic substrate and a plurality of second detection electrodes 32A extending in a second direction orthogonal to the first direction in a plane on the other surface of the acrylic substrate.

The detection electrode may be disposed only one on one surface of the acrylic substrate. In addition, the first detection electrode 31A and the second detection electrode 32A may be laminated and disposed only on one surface of the acrylic substrate with the insulating layer interposed therebetween.

The detection electrode may have a predetermined pattern formed of a fine metal wire. The pattern to be formed is not particularly limited, and it is preferably a mesh shape (mesh pattern). The mesh shape means a shape including a plurality of opening portions (lattices) formed of intersecting fine metal wires as shown in FIG. 2. It is preferable that the detection electrode has a mesh pattern formed of a fine metal wire.

FIG. 2 is a plan view showing an example of a configuration of a first detection electrode 31A of the touch sensor. In the first detection electrode 31A of the touch sensor shown in FIG. 2, a mesh pattern in which the shape of the opening portion 33 is a square having one side length of L is formed of the fine metal wire 31.

Examples of the shape of the mesh pattern of the detection electrode include a triangle such as an equilateral triangle, an isosceles triangle, or a right triangle, a quadrangle such as a square, a rectangle, a rhombus, a parallelogram, or a trapezoid, a (regular) n-sided polygon such as a (regular) hexagon or a (regular) octagon, a circle, an ellipse, and geometric figures formed by combining a star shape or the like. In addition, in the opening portion, the shape of one side may be a curved shape or may be an arc shape in addition to a linear shape. In a case where the shape of one side is an arc shape, for example, two sides facing each other may have an arc shape that is outwardly convex, and the other two sides facing each other may have an arc shape that is inwardly convex. In addition, the shape of each of the sides may have a wavy line shape in which an arc that is outwardly convex and an arc that is inwardly convex are continuous. Of course, the shape of each of the sides may be a sine curve shape. The mesh pattern is not particularly limited, and may be a random pattern or a regular pattern or may be a regular mesh pattern in which a plurality of congruent shapes are repeatedly disposed.

As the mesh pattern of the detection electrode, a regular mesh pattern having a rhombic opening portion having the same shape is preferable from the viewpoint of reducing an interference pattern (moiré) with the pixel pattern of the display panel. A preferred angle of the acute angle of the rhombus is 20 to 70 degrees. The length L of one side of the opening portion is preferably 100 to 1,000 μm and more preferably 150 to 600 μm from the viewpoint of visibility. In a case where the length of one side of the opening portion is within the above-described range, it is possible to maintain good transparency, and in the display device, a display image can be visually recognized without any sense of incongruity.

The opening ratio of the mesh pattern of the detection electrode is preferably 90% or more, and more preferably 95% or more from the viewpoint of visible light transmittance. The upper limit thereof is not particularly limited; however, it may be less than 100%. The opening ratio corresponds to the area ratio of the opening portion excluding the fine metal wire in the region where the detection electrode is provided to the entire region where the detection electrode is provided.

The mesh pattern of the detection electrode can be observed and measured using an optical microscope.

The line width of the fine metal wire constituting the detection electrode is preferably 10 μm or less, more preferably 5 μm or less, and still more preferably 2.5 μm or less from the viewpoint of more excellent visibility. The lower limit value thereof is not particularly limited, but from the viewpoint of more excellent conductive characteristics of the fine metal wires, it is preferably 1.0 μm or more, and more preferably 1.5 μm or more.

In addition, the height of the fine metal wire is not particularly limited, but is, for example, 0.1 to 10 μm, and preferably 0.3 to 5 μm.

The line width and height of the fine metal wire are obtained by selecting fine metal wires at any five positions using a scanning electron microscope and arithmetically averaging values corresponding to the measured line widths and heights.

The fine metal wire contains a metal.

As the metal, from the viewpoint of more excellent conductivity, silver (metallic silver), copper (metallic copper), gold (metallic gold), nickel (metallic nickel), palladium (metallic palladium), or a mixture of two or more kinds thereof is preferable, silver, copper, or a mixture thereof is more preferable, and copper is still more preferable.

The form of the metal in the fine metal wire is not limited, and examples thereof include a particulate form and a form in which the metal is layered and dispersed in the fine metal wire.

The fine metal wire may be a fine metal wire containing silver metal and a polymer binder such as gelatin and acrylic styrene latex, which is suitable for forming a mesh pattern. In a case where the fine metal wire includes a polymer binder, the metal particles may be present in a polymer in a dispersed manner, or the metal particles may be aggregated in a polymer and present as an aggregate. The kind of the polymer is not particularly limited, and a well-known polymer can be used.

The fine metal wire may be a fine metal wire composed of metals of aluminum, copper, silver, molybdenum, and titanium, and alloys thereof. In addition, a laminated structure of the materials may be used. For example, a fine metal wire having a laminated structure such as molybdenum/copper/molybdenum or molybdenum/aluminum/molybdenum can be used.

Other members other than the detection electrode may be disposed on the surface of the acrylic substrate.

Examples of the other members include an electrode connection terminal formed at one end of the detection electrode, a peripheral wiring line electrically connected to the electrode connection terminal, and an external connection terminal electrically connected to the peripheral wiring line and an external device. These members have a function of transmitting the electric signal detected by the detection electrode to an external device.

In addition, a dummy electrode may be disposed on the surface of the acrylic substrate as another member. The dummy electrode is disposed between the detection electrodes. It is preferable that the dummy electrode is also composed of a fine metal wire, as in the case of the detection electrode.

### Method for Manufacturing Touch Sensor

The manufacturing method of the touch sensor is not particularly limited as long as it is a method capable of forming the detection electrode on at least one surface of the acrylic substrate. As a method for forming the detection electrode, for example, a sputtering method, a plating method, a silver salt method, a printing method, and the like can be appropriately used.

A method of forming a detection electrode by a sputtering method will be described. First, a copper foil layer is formed by sputtering, and a copper wire is formed from the copper foil layer by a photolithography method, whereby a detection electrode can be formed. It is noted that the copper foil layer can also be formed by so-called vapor deposition instead of sputtering. As the copper foil layer, an electrolytic copper foil can be used in addition to a sputtered copper foil or a vapor deposited copper foil. More specifically, a step of forming copper wires described in JP2014-029614A can be used.

A method of forming a detection electrode by a plating method will be described. For example, by subjecting the electroless plating underlayer to electroless plating, a metal plating film is formed on the underlayer. This metal plating film can be used as a detection electrode. In this case, the detection electrode is formed by forming a catalyst ink containing at least metal fine particles in a patterned manner on an acrylic substrate and then immersing the acrylic substrate in an electroless plating bath to form a metal plating film. More specifically, a method of manufacturing a metal-coated substrate described in JP2014-159620A can be used.

In addition, the detection electrode is formed by forming a resin composition having at least a functional group capable of interacting with a metal catalyst precursor in a patterned manner on an acrylic substrate, applying a catalyst or a catalyst precursor, and immersing the acrylic substrate in an electroless plating bath to form a metal plating film. More specifically, a method of manufacturing a metal-coated substrate described in JP2012-144761A can be used.

A method of forming a detection electrode by a silver salt method will be described. First, the silver-salt emulsion layer containing silver salt is subjected to an exposure treatment using an exposure pattern corresponding to the pattern of the detection electrode, and then a development treatment is performed, whereby the detection electrode can be formed. More specifically, a method of manufacturing the fine metal wire described in JP2012-006377A, JP2014-112512A, JP2014-209332A, JP2015-022397A, JP2016-192200A, or WO2016/157585A can be used.

A method of forming a detection electrode by a printing method will be described. First, the conductive paste containing the conductive powder is applied to the substrate in the same pattern as the detection electrode, and then the detection electrode can be formed by performing a heating treatment. The pattern formation using the conductive paste is performed, for example, using an ink jet method or a screen printing method. More specifically, as a conductive paste, the conductive paste described in JP2011-028985A can be used.

### Second Pressure-Sensitive Adhesive Layer

The second pressure-sensitive adhesive layer is a layer that is disposed between the touch sensor and the OLED panel and has a function of fixing the touch sensor and the OLED panel to each other, and the thickness thereof is 100 μm or less.

The constituent components of the second pressure-sensitive adhesive layer are not particularly limited as long as they are components that exhibit the above-described functions.

It is preferable that the second pressure-sensitive adhesive layer is transparent and has electrical insulating properties.

It is preferable that the second pressure-sensitive adhesive layer contains a pressure sensitive adhesive.

Examples of the pressure sensitive adhesive used for the second pressure-sensitive adhesive layer include an optically transparent pressure sensitive adhesive (optical clear adhesive, OCA) and an optically transparent resin (optical clear resin, OCR) such as an ultra violet (UV) curable resin.

Examples of the OCA and the OCR include an acrylic resin, a urethane acrylate resin, a urethane resin, a rubber-based resin, an epoxy resin, an epoxy acrylate resin, an oxetane resin, a silicone resin, a silicone acrylic resin, a polyester resin, a polyether resin (polyvinyl ether and the like), a polyamide resin, a fluororesin, a vinyl acetate/vinyl chloride copolymer, and a modified polyolefin. Only one kind of the resin may be used, or two or more kinds thereof may be used.

Among these, an acrylic resin is preferable from the viewpoint of further improving the effects of the present invention and the viewpoint of weather fastness and cost.

The content of the pressure sensitive adhesive (more preferably an acrylic resin) in the second pressure-sensitive adhesive layer is preferably 85% by mass or more, and more preferably 90% by mass or more with respect to the total mass of the second pressure-sensitive adhesive layer. The upper limit value thereof is not particularly limited, and may be, for example, 99% by mass or less. In addition, the content of the pressure sensitive adhesive in the second pressure-sensitive adhesive layer may be the remainder of the visible light absorbing material and any additive.

The second pressure-sensitive adhesive layer may optionally contain an additive as long as the function as a pressure-sensitive adhesive layer and the effects of the present invention are not impaired. Examples of the additive include a crosslinking agent, an ultraviolet absorber, a plasticizer, an antistatic agent, and a corrosion inhibitor.

The thickness of the second pressure-sensitive adhesive layer is 100 μm or less, and from the viewpoint that the effects of the present invention are more excellent, the thickness is preferably 75 μm or less and more preferably 50 μm or less, and from the viewpoint that the effects of the present invention and the sensitivity of the touch panel are more excellent, the thickness is preferably 5 μm or more, more preferably 25 μm or more, and still more preferably 50 μm or more. In a case where the thickness of the second pressure-sensitive adhesive layer is equal to or larger than the above-described lower limit value, it is presumed that the malfunction of the touch sensor due to the noise signal flowing in the OLED panel is suppressed, and thus the sensitivity of the touch panel is improved.

The total of the thickness of the acrylic substrate and the thickness of the second pressure-sensitive adhesive layer in the present display device is, for example, 35 μm or more, and is preferably 56 μm or more and more preferably 80 μm or more from the viewpoint that the effect of the present invention is more excellent.

In addition, the total of the thickness of the acrylic substrate and the thickness of the second pressure-sensitive adhesive layer is 140 μm or less, preferably 100 μm or less, and more preferably 90 μm or less.

The relative permittivity of the second pressure-sensitive adhesive layer at a frequency of 100 kHz is preferably 4.0 or less, more preferably 3.5 or less, and still more preferably 3.0 or less. The lower limit value is not particularly limited, and may be, for example, 2.0 or more.

In a case where the relative permittivity of the second pressure-sensitive adhesive layer is equal to or less than the above-described upper limit value, the performance of blocking the influence of electromagnetic noise from the OLED panel is more excellent. The relative permittivity is obtained in accordance with JIS K 6911:2006.

As a method of forming the second pressure-sensitive adhesive layer, various known methods can be applied.

Examples of a method of forming the second pressure-sensitive adhesive layer include a method (a coating method) of forming the second pressure-sensitive adhesive layer by applying a pressure-sensitive adhesive composition containing a pressure-sensitive adhesive formed of the above-described resin onto the surface of the touch sensor, and a method (a transfer method) of forming the second pressure-sensitive adhesive layer on a temporary support using the above-described pressure-sensitive adhesive composition and then transferring the second pressure-sensitive adhesive layer to the surface of the touch sensor on which the detection electrodes are disposed.

Among these, the transfer method is preferable from the viewpoint that the yield of the touch panel display device can be increased by individually producing and inspecting the touch sensor and the second pressure-sensitive adhesive layer and using the good products.

A drying treatment may be performed on the coating film of the pressure sensitive adhesive composition formed on the surface of the touch sensor or the temporary support, as necessary. As the method of applying the pressure sensitive adhesive composition and the drying treatment of the coating film, known methods can be applied.

The pressure sensitive adhesive composition used for forming the pressure-sensitive adhesive layer may further include the above-described additive in addition to the pressure sensitive adhesive. In addition, the pressure sensitive adhesive composition may further contain a coating aid such as a solvent, a surfactant, and a thickener.

It is preferable that the pressure sensitive adhesive composition further contains a solvent. Examples of the solvent include water and an organic solvent, and a solvent capable of dissolving or dispersing components such as a pressure sensitive adhesive and a visible light absorbing material is appropriately selected.

In a case where the pressure sensitive adhesive composition contains a solvent, the concentration of solid contents of the pressure sensitive adhesive composition is preferably 5% to 60% by mass, and more preferably 10% to 50% by mass. The “solid content” of the pressure sensitive adhesive composition means components constituting a pressure sensitive-adhesive layer formed of the pressure sensitive adhesive composition, and in a case where the pressure sensitive adhesive composition contains a solvent, it means all components excluding the solvent. In a case where the component is a component that forms a pressure-sensitive adhesive layer, the component is also regarded as a solid content.

### First Pressure-Sensitive Adhesive Layer

The first pressure-sensitive adhesive layer is a layer that is disposed between the cover member and the touch sensor and has a function of fixing the cover member and the touch sensor.

The constituent components and the thickness of the first pressure-sensitive adhesive layer are not particularly limited as long as they are components that exhibit the above-described functions.

It is preferable that the first pressure-sensitive adhesive layer is transparent and has electrical insulating properties.

The thickness of the first pressure-sensitive adhesive layer is, for example, 250 μm or less, and from the viewpoint that the effect of the present invention is more excellent, is preferably 125 μm or less and more preferably 100 μm or less.

The lower limit of the thickness of the first pressure-sensitive adhesive layer is not particularly limited, but is, for example, 5 μm or more, and is preferably 75 μm or more from the viewpoint that the adhesiveness between the cover member and the touch sensor is more excellent.

In the present display device, the total thickness of the acrylic substrate, the first pressure-sensitive adhesive layer, and the second pressure-sensitive adhesive layer is, for example, 136 to 265 μm, and is preferably 150 to 200 μm from the viewpoint that the contrast and the moisture-heat resistance are more excellent.

The constituent component and the relative permittivity of the first pressure-sensitive adhesive layer may be the same as those of the second pressure-sensitive adhesive layer, but it is preferable that at least one of the constituent component or the relative permittivity is different. In particular, it is preferable that the relative permittivity of the second pressure-sensitive adhesive layer is smaller than the relative permittivity of the first pressure-sensitive adhesive layer from the viewpoint of improving the sensitivity of the touch panel.

A preferred relative permittivity of the first pressure-sensitive adhesive layer at a frequency of 100 kHz is 3.5 or more and more preferably 4.0 or more, and a difference between the relative permittivity of the first pressure-sensitive adhesive layer and the relative permittivity of the second pressure-sensitive adhesive layer ((relative permittivity of first pressure-sensitive adhesive layer at frequency of 100 kHz)−(relative permittivity of second pressure-sensitive adhesive layer at frequency of 100 kHz)) is preferably 1.0 or more from the viewpoint of improving the sensitivity of the touch panel.

In addition, it is preferable that the first pressure-sensitive adhesive layer and the second pressure-sensitive adhesive layer contain the same type of pressure-sensitive adhesive, and from the viewpoint that the effect of the present invention is more excellent, it is preferable that both the first pressure-sensitive adhesive layer and the second pressure-sensitive adhesive layer contain an acrylic resin.

In addition, from the viewpoint that the effect of the present invention is more excellent, it is more preferable that the thickness of the first pressure-sensitive adhesive layer is larger than the thickness of the second pressure-sensitive adhesive layer. It is preferable that the thickness of the first pressure-sensitive adhesive layer is larger than the thickness of the acrylic substrate from the viewpoint of increasing the strength of the touch panel display device.

### OLED Panel

The OLED panel provided in the present display device is not particularly limited as long as it is a display panel using an organic EL element.

The display device can be used as a touch panel display device having a touch detection function by comprising an OLED panel and a touch sensor. In addition, since the display device comprises the OLED panel, the overall thickness of the display device can be further reduced, and image quality with excellent contrast can be provided.

### Cover Member

The touch panel display device has a cover member on a visible side of the touch sensor.

In the touch panel display device 10 shown in FIG. 1, a surface 5a of the cover member 5 on the visible side is a touch surface and an operation surface of the touch panel display device 10. That is, the surface 5a of the cover member 5 on the visible side is input-operated as the operation surface. The touch surface means a surface that detects contact of a finger, a stylus pen, or the like.

Since the surface of the cover member is a touch surface, a hard coat layer may be provided on the surface as necessary. In addition, it is preferable that a surface of the cover member is subjected to a treatment of imparting various functions such as an anti-scratch treatment, an anti-glare treatment, an anti-fouling treatment, an anti-fogging treatment, and an anti-reflection treatment.

The configuration of the cover member is not particularly limited, but it is preferable that the cover member is transparent so that an image displayed on the display surface of the OLED panel can be visually recognized. As the cover member, for example, a transparent glass substrate such as chemically strengthened glass, a sapphire substrate, and a transparent plastic substrate such as PMMA, PET, and polycarbonate are used.

The cover member, which is a transparent glass substrate, is also referred to as a cover lens or cover glass.

The refractive index of the cover member is preferably 1.40 to 1.70. The difference in refractive index between the cover member and the other member is preferably 0.1 or less.

It is preferable that the thickness of the cover member is appropriately selected according to each application.

In the cover member, a decorative layer may be provided in a non-display area region where an image of the OLED panel is not displayed, using black ink or the like.

Basically, the present invention is configured as described above. The present invention is not limited to the above-described embodiments, and various improvements or modifications may be made without departing from the spirit of the present invention.

### EXAMPLES

Hereinbelow, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### Example 1

As an acrylic substrate, a PMMA film having a thickness of 40 μm was prepared.

A detection electrode having a mesh pattern composed of a fine metal wire was produced on both surfaces of the PMMA film according to the method described in the step 1 of Example 1 of WO2022/071273A. Specifically, first, a conductive layer consisting of a copper nitride film (blackening layer), a copper film, and a copper nitride film (blackening layer) was formed on both surfaces of the PMMA film by sputtering. The thicknesses of the copper nitride film, the copper film, and the copper nitride film were 38 nm, 500 nm, and 38 nm, respectively.

Next, the conductive layer was patterned by a photolithography method. More specifically, a resist film was formed on the surface of the conductive layer, the conductive layer was exposed in a state where the photo mask was disposed on the resist film, and the exposed resist film was developed to obtain a resist film having a pattern corresponding to the photo mask. Using the resist film as a mask, the conductive layer was etched using an etchant, and then the resist film was peeled off to manufacture a touch sensor 1 having a detection electrode consisting of a regular mesh pattern, an electrode connection terminal formed at an end part of the detection electrode, a lead wire connected to the electrode connection terminal, and an external connection terminal connected to the lead wire on both surfaces of the PMMA film. In the mesh pattern of the detection electrode of the touch sensor 1, rhombic mesh cells (acute angle: 60 degrees, one side length: 500 μm) composed of fine metal wires having a line width of 2.5 μm were arranged side by side.

A cover member 5 consisting of chemically strengthened glass having a thickness of 0.4 mm was bonded to one main surface of the touch sensor 1 with an OCA 1 (manufactured by 3M, “8146-5”, first pressure-sensitive adhesive layer) consisting of an acrylic resin having a thickness of 125 μm interposed therebetween. Next, an OLED panel (manufactured by Samsung Display Co., Ltd., model number “ATNA40CU03”) was bonded to the other main surface of the touch sensor 1 via an OCA (manufactured by SHIN-TAK Co., Ltd., “SA364GF”, second pressure-sensitive adhesive layer) consisting of an acrylic resin having a thickness of 100 μm. In this manner, a touch panel display device of Example 1 including the OLED panel, the second pressure-sensitive adhesive layer, the touch sensor, the first pressure-sensitive adhesive layer, and the cover member in this order was prepared.

A flexible printed circuit (FPC) for connection to a touch drive integrated circuit (IC) was connected to the external connection terminal of the touch sensor 1 via an anisotropic conductive film in advance.

### Examples 2 to 11 and Comparative Examples 1 to 6

For any of the acrylic substrate, the first pressure-sensitive adhesive layer, and the second pressure-sensitive adhesive layer, touch panel display devices of Examples 2 to 11 and Comparative Examples 1 to 6 were produced as described below using the members described in Table 1 in the latter part.

A touch panel display device of Example 2 was prepared in the same manner as in Example 1, except that the acrylic substrate of Example 1 was changed to a PMMA film having a thickness of 31 μm.

A touch panel display device of Example 3 was prepared in the same manner as in Example 1, except that the second pressure-sensitive adhesive layer of Example 1 was changed to OCA (manufactured by SHINTACK CO., LTD., “SA362GF”) consisting of an acrylic resin having a thickness of 50 μm.

A touch panel display device of Example 4 was prepared in the same manner as in Example 1, except that the first pressure-sensitive adhesive layer of Example 1 was changed to OCA (manufactured by 3M, “8146-4”) consisting of an acrylic resin having a thickness of 100 μm.

A touch panel display device of Example 5 was prepared in the same manner as in Example 4, except that the second pressure-sensitive adhesive layer of Example 4 was changed to OCA (manufactured by New Tac Co., Ltd., “SA362GF”) consisting of an acrylic resin having a thickness of 50 μm.

A touch panel display device of Example 6 was prepared in the same manner as in Example 5 except that the acrylic substrate of Example 5 was changed to a PMMA film having a thickness of 31 μm.

A touch panel display device of Example 7 was prepared using the same method as that of Example 4, except that the second pressure-sensitive adhesive layer of Example 4 was changed to OCA (manufactured by Shin-Tak Co., Ltd., “SA361GF”) consisting of an acrylic resin having a thickness of 25 μm.

A touch panel display device of Example 8 was prepared in the same manner as in Example 7 except that the acrylic substrate of Example 7 was changed to a PMMA film having a thickness of 31 μm.

A touch panel display device of Example 9 was prepared in the same manner as in Example 4, except that the second pressure-sensitive adhesive layer of Example 4 was changed to OCA (manufactured by LINTEC Corporation, “NCF-F619”) consisting of an acrylic resin having a thickness of 5 μm.

A touch panel display device of Example 10 was prepared using the same method as that of Example 9, except that the acrylic substrate of Example 9 was changed to a PMMA film having a thickness of 31 μm.

A touch panel display device of Example 11 was prepared using the same method as that of Example 1, except that the acrylic substrate of Example 1 was changed to a polyacrylonitrile (PAN) film having a thickness of 40 μm.

A touch panel display device of Comparative Example 1 was prepared in the same manner as in Example 1, except that the acrylic substrate of Example 1 was changed to a PMMA film having a thickness of 50 μm, and the second pressure-sensitive adhesive layer was changed to an OCA (manufactured by SHIN-TAK Co., Ltd., “SA366GF”) consisting of an acrylic resin and having a thickness of 125 μm.

A touch panel display device of Comparative Example 2 was prepared in the same manner as in Example 1, except that the second pressure-sensitive adhesive layer of Example 1 was changed to OCA (manufactured by SHINTACK CO., LTD., “SA366GF”) consisting of an acrylic resin having a thickness of 125 μm.

A touch panel display device of Comparative Example 3 was prepared in the same manner as in Example 1, except that the acrylic substrate of Example 1 was changed to a PMMA film having a thickness of 50 μm.

A touch panel display device of Comparative Example 4 was prepared in the same manner as in Example 5, except that the acrylic substrate of Example 5 was changed to a PMMA film having a thickness of 50 μm.

A touch panel display device of Comparative Example 5 was prepared in the same manner as in Example 5, except that the acrylic substrate of Example 5 was changed to a film made of polyethylene terephthalate (PET) having a thickness of 38 μm.

In addition, a touch panel display device of Comparative Example 6 was prepared in the same manner as in Example 5, except that the acrylic substrate of Example 5 was changed to a film made of triacetyl cellulose (TAC) having a thickness of 40 μm.

As a result of measuring the relative permittivity of the first pressure-sensitive adhesive layer and the second pressure-sensitive adhesive layer of the touch panel display devices of Examples 1 to 11 at a frequency of 100 kHz, the relative permittivity of the first pressure-sensitive adhesive layer of each of Examples was 4.1, the relative permittivity of the second pressure-sensitive adhesive layer of each of Examples 1 to 8 and 11 was 2.9, and the relative permittivity of the second pressure-sensitive adhesive layer of each of Examples 9 and 10 was 4.8.

### Evaluation

### (1) Contrast

In a dark room without a window, the touch panel display device was installed such that the display surface faced vertically upward. A square image of white ((R, G, B)=(255, 255, 255)) of 80 mm×80 mm was displayed at the center of the screen of the touch panel display device, and an image of black ((R, G, B)=(0, 0, 0)) was displayed over the entire periphery of the white display image. A cylinder (diameter: 60 mm, length: 350 mm) produced by rolling black thick paper was vertically placed on a white display portion of the touch panel display device such that the center of the white display portion and the central axis of the cylinder substantially coincided with each other, and the cylinder was vertically placed with respect to the display surface. A spectral radiance meter (CS-3000HDR, manufactured by Konica Minolta, Inc.) was set at the tip of the cylinder, and the brightness of the image displayed by the touch panel display device was measured under the following measurement conditions. Next, the output brightness of the touch panel display device was adjusted such that the brightness of the measured white display portion was approximately 500 cd/m², and the measured brightness of the white display portion was denoted as L_{W}.

### Brightness Measurement Conditions

Speed mode: FAST
Dark setting: standard
Aperture angle: 1 deg

Next, while maintaining the output brightness (brightness of the white display portion) of the touch panel display device, the position of the black display portion and the white display portion of the touch panel display device was switched (a square image of black ((R, G, B)=(0, 0, 0)) of 80 mm×80 mm was displayed at the center of the screen, and an image of white ((R, G, B)=(255, 255, 255)) was displayed in the entire periphery of the black display image), the cylinder was vertically erected so that the center of the black display image and the central axis of the cylinder substantially coincided with each other, and the brightness was measured using the spectral radiance meter under the above measurement conditions. The measured brightness of the black display portion was denoted by L_{B}.

A ratio (L_{W}/L_{B}) of the brightness L_{W} of the white display portion to the brightness L_{B} of the black display portion obtained above was calculated as a contrast ratio. From the calculated contrast ratio, the contrast between the black display and the white display in a case where the black-and-white display was performed for each touch panel display device was evaluated based on the following standards.

### Contrast Evaluation Standard

“AA”: The contrast ratio is 2,500,000 or more.
“A”: The contrast ratio is 2,000,000 or more and less than 2,500,000.
“B”: The contrast ratio is 1,250,000 or more and less than 2,000,000.
“C”: The contrast ratio is 1,000,000 or more and less than 1,250,000.
“D”: contrast ratio was less than 1,000,000.

### (2) Moisture-Heat Resistance

A moisture-heat test in which the touch panel display device was stored for 48 hours in an environment of a temperature of 60° C. and a humidity of 90% RH was performed, and the contrast ratio of the touch panel display device after the moisture-heat test was obtained in the same manner as in (1) above. A value calculated by the expression (C_{B}/C_{A}) from the contrast ratio C_{B} before the wet heat test and the contrast ratio C_{A} after the wet heat test was defined as a contrast ratio deterioration rate.

From the contrast ratio deterioration rate obtained for the touch panel display device of each example, the moisture-heat resistance of each touch panel display device was evaluated based on the following standards.

### Evaluation Standard for Moisture-Heat Resistance

“A”: contrast ratio deterioration rate was less than 2.
“B”: contrast ratio deterioration rate was 2 or more and less than 5.
“C”: contrast ratio deterioration rate was 2 or more and less than 10.
“D”: contrast ratio deterioration rate was 10 or more.

### (3) Touch Panel Sensitivity

An image of white ((R, G, B)=(255, 255, 255)) was displayed on the entire surface of the display surface of the touch panel display device, and the brightness was adjusted to 500 cd/m².

In a case where a stylus pen having a tip diameter of 2 mm was brought into contact with a touch surface (exposed surface) of the cover glass and the stylus pen was moved from one vertex to the other vertex along the diagonal line of the displayed white image, the motion response of the cursor displayed on the OLED panel was visually observed. From the observation result of the motion response of the cursor according to the movement of the stylus pen, the touch panel sensitivity of each touch panel display device was evaluated based on the following standards.

### Evaluation Standard for Touch Panel Sensitivity

“A”: The cursor is operated without any delay even in a case where the stylus pen is moved at a high speed.
“B”: Even in a case where the stylus pen is moved at a high speed, the cursor operates without any practical problem.
“C”: The cursor operates without any practical problem only in a case where the stylus pen is moved at a low speed.
“D”: There is a deviation between the position of the stylus pen and the position of the cursor.

Table 1 shows the configuration of the touch panel display device of each example and the evaluation results.

TABLE 1

| | Thickness | | | Thickness | | | |
|---|---|---|---|---|---|---|---|
| | of first | | | of second | | | |
| | pressure- | | | pressure- | | | |
| | sensitive | | | sensitive | Evaluation | | |
| | adhesive | Substate | | adhesive | | Moisture- | Touch |
| | layer | | Thickness | layer | | heat | panel |
| | (μm) | Material | (μm) | (μm) | Contrast | resistance | sensitivity |
| Example 1 | 125 | PMMA | 40 | 100 | C | A | A |
| Example 2 | 125 | PMMA | 31 | 100 | B | A | A |
| Example 3 | 125 | PMMA | 40 | 50 | B | A | A |
| Example 4 | 100 | PMMA | 40 | 100 | B | A | A |
| Example 5 | 100 | PMMA | 40 | 50 | A | A | A |
| Example 6 | 100 | PMMA | 31 | 50 | AA | A | A |
| Example 7 | 100 | PMMA | 40 | 25 | A | A | B |
| Example 8 | 100 | PMMA | 31 | 25 | AA | A | B |
| Example 9 | 100 | PMMA | 40 | 5 | A | B | C |
| Example 10 | 100 | PMMA | 31 | 5 | AA | B | C |
| Example 11 | 100 | PAN | 40 | 100 | C | B | B |
| Comparative | 125 | PMMA | 50 | 125 | D | A | A |
| Example 1 | | | | | | | |
| Comparative | 125 | PMMA | 40 | 125 | D | A | A |
| Example 2 | | | | | | | |
| Comparative | 125 | PMMA | 50 | 100 | D | A | A |
| Example 3 | | | | | | | |
| Comparative | 100 | PMMA | 50 | 50 | D | A | A |
| Example 4 | | | | | | | |
| Comparative | 100 | PET | 38 | 25 | D | A | B |
| Example 5 | | | | | | | |
| Comparative | 100 | TAC | 40 | 25 | C | D | C |
| Example 6 | | | | | | | |

From the results in Table 1, it was confirmed that the touch panel display devices of the present invention of Examples 1 to 11 have excellent contrast between black display and white display in a case of black-and-white display, and have excellent performance of suppressing a decrease in contrast in a high temperature and high humidity environment.

On the other hand, in the touch panel display devices of Comparative Examples 1 to 4 in which the thickness of the acrylic substrate was more than 40 μm or the thickness of the second pressure-sensitive adhesive layer was more than 100 μm, the improvement of the contrast was insufficient.

In addition, in the touch panel display device of Comparative Example 5 in which the substrate of the touch sensor is a PET substrate, the improvement of the contrast is insufficient, and in the touch panel display device of Comparative Example 6 in which the substrate of the touch sensor is a TAC substrate, the performance of suppressing the decrease in contrast in a high temperature and high humidity environment is insufficient.

From the comparison between Examples 1 and 2 and the comparison between Examples 5 and 6, it was confirmed that in a case where the thickness of the acrylic substrate was 35 μm or less, the contrast between the black display and the white display in the black-and-white display was more excellent.

From the comparison between Examples 1 and 3 and the comparison between Examples 4 and 5, it was confirmed that in a case where the thickness of the second pressure-sensitive adhesive layer was 50 μm or less, the contrast between the black display and the white display in the black-and-white display was more excellent.

From the comparison between Examples 1 and 4 and the comparison between Examples 3 and 5, it was confirmed that in a case where the thickness of the first pressure-sensitive adhesive layer was 100 μm or less, the contrast between the black display and the white display in the black-and-white display was more excellent.

From the comparison between Examples 7 and 9 and the comparison between Examples 8 and 10, it was confirmed that in a case where the thickness of the second pressure-sensitive adhesive layer was 25 μm or more, the performance of suppressing a decrease in contrast in a high-temperature and high-humidity environment was more excellent.

From the comparison of Examples 5, 7, and 9 and the comparison of Examples 6, 8, and 10, it was confirmed that in a case where the total of the thickness of the acrylic substrate and the thickness of the second pressure-sensitive adhesive layer was 56 μm or more, the sensitivity of the touch panel was more excellent, and in a case where the total of the thickness of the acrylic substrate and the thickness of the second pressure-sensitive adhesive layer was 80 μm or more, the sensitivity of the touch panel was further improved.

Further, from the comparison between Examples 1 and 11, it was confirmed that, in the acrylic substrates, the heat resistance and the sensitivity of the touch panel were more excellent in a case where the PMMA film was used than in a case where the PAN film was used.

### EXPLANATION OF REFERENCES

1: OLED panel
1a: display surface
2: second pressure-sensitive adhesive layer
3: touch sensor
3a, 3b, 5a: surface
4: first pressure-sensitive adhesive layer
5: cover member
10: touch panel display device
30: acrylic substrate
31, 32: fine metal wire
31A: first detection electrode
32A: second detection electrode
33: opening portion

What is claimed is:

1. A touch panel display device comprising, in the following order:
a cover member;
a first pressure-sensitive adhesive layer;
a touch sensor;
a second pressure-sensitive adhesive layer; and
an organic electroluminescence display panel,
wherein the touch sensor has an acrylic substrate,
a thickness of the acrylic substrate is 40 μm or less, and
a thickness of the second pressure-sensitive adhesive layer is 100 μm or less.

2. The touch panel display device according to claim 1,
wherein the acrylic substrate includes polymethyl methacrylate.

3. The touch panel display device according to claim 1,
wherein the thickness of the acrylic substrate is 35 μm or less.

4. The touch panel display device according to claim 2,
wherein the thickness of the acrylic substrate is 35 μm or less.

5. The touch panel display device according to claim 1,
wherein the thickness of the second pressure-sensitive adhesive layer is 50 μm or less.

6. The touch panel display device according to claim 1,
wherein a total of the thickness of the acrylic substrate and the thickness of the second pressure-sensitive adhesive layer is 56 μm or more.

7. The touch panel display device according to claim 1,
wherein the thickness of the second pressure-sensitive adhesive layer is 50 μm or less, and
a total of the thickness of the acrylic substrate and the thickness of the second pressure-sensitive adhesive layer is 56 μm or more.

8. The touch panel display device according to claim 2,
wherein the thickness of the second pressure-sensitive adhesive layer is 50 μm or less, and
a total of the thickness of the acrylic substrate and the thickness of the second pressure-sensitive adhesive layer is 56 μm or more.

9. The touch panel display device according to claim 3,
wherein the thickness of the second pressure-sensitive adhesive layer is 50 μm or less, and
a total of the thickness of the acrylic substrate and the thickness of the second pressure-sensitive adhesive layer is 56 μm or more.

10. The touch panel display device according to claim 1,
wherein a thickness of the first pressure-sensitive adhesive layer is 100 μm or less.

11. The touch panel display device according to claim 2,
wherein a thickness of the first pressure-sensitive adhesive layer is 100 μm or less.

12. The touch panel display device according to claim 3,
wherein a thickness of the first pressure-sensitive adhesive layer is 100 μm or less.

13. The touch panel display device according to claim 7,
wherein a thickness of the first pressure-sensitive adhesive layer is 100 μm or less.

14. The touch panel display device according to claim 1,
wherein a relative permittivity of the second pressure-sensitive adhesive layer at a frequency of 100 kHz is 3.5 or less.

15. The touch panel display device according to claim 1,
wherein both the first pressure-sensitive adhesive layer and the second pressure-sensitive adhesive layer contain an acrylic resin.

16. The touch panel display device according to claim 1,
wherein the touch sensor has a detection electrode disposed on at least one surface of the acrylic substrate, and
the detection electrode has a mesh pattern formed of fine metal wires.

17. The touch panel display device according to claim 16,
wherein a line width of the fine metal wires is 2.5 μm or less.
